(19) United States
(12) Patent Application Publication
(10) Pub. No.: US 2013/0280891 A1
(43) Pub. Date: Oct. 24, 2013

(54) METHOD AND APPARATUS FOR GERMANIUM TIN ALLOY FORMATION BY THERMAL CVD

(71) Applicants: YIHWAN KIM, San Jose, CA (US); Yi-Chiau Huang, Fremont, CA (US); Errol Antonio C. Sanchez, Tracy, CA (US)

(72) Inventors: YIHWAN KIM, San Jose, CA (US); Yi-Chiau Huang, Fremont, CA (US); Errol Antonio C. Sanchez, Tracy, CA (US)

(21) Appl. No.: 13/784,109

(22) Filed: Mar. 29, 2013

Related U.S. Application Data
(60) Provisional application No. 61/635,978, filed on Apr. 20, 2012.

(51) Int. Cl. H01L 21/02

(52) U.S. Cl. CPC H01L 21/0262
USPC 438/478

(57) ABSTRACT

A method and apparatus for forming semiconductive semiconductor-metal alloy layers is described. A germanium precursor and a metal precursor are provided to a chamber, and an epitaxial layer of germanium-metal alloy, optionally including silicon, is formed on the substrate. The metal precursor is typically a metal halide, which may be provided by evaporating a liquid metal halide, subliming a solid metal halide, or by contacting a pure metal with a halogen gas. A group IV halide deposition control agent is used to provide selective deposition on semiconductive regions of the substrate relative to dielectric regions. The semiconductive semiconductor-metal alloy layers may be doped, for example with boron, phosphorus, and/or arsenic. The precursors may be provided through a showerhead or through a side entry point, and an exhaust system coupled to the chamber may be separately heated to manage condensation of exhaust components.

### CROSS-REFERENCE TO RELATED APPLICATIONS

This application claims benefit of U.S. provisional patent application Ser. No. 61/635,978, filed Apr. 20, 2013, which is herein incorporated by reference.

### BACKGROUND OF THE INVENTION

1. Field of the Invention

Technology described herein relates to manufacture of semiconductor devices. More specifically, methods are described of forming group IV semiconductive semiconductor-metal alloy layers in both field effect transistors and photonic devices such as lasers.

2. Description of the Related Art

Germanium was one of the first materials used for semiconductor applications such as CMOS transistors. Due to vast abundance of silicon compared to germanium, however, silicon has been the overwhelming semiconductor material of choice for CMOS manufacture. As device geometries decline according to Moore's Law, the size of transistor components poses challenges to engineers working to make devices that are smaller, faster, use less power, and generate less heat. For example, as the size of a transistor declines, the channel region of the transistor becomes smaller, and the electronic properties of the channel become less viable, with more resistivity and higher threshold voltages. Carrier mobility is increased in the silicon channel area by using silicon-germanium stressors embedded in the source/drain areas, as some manufacturers have done for the 45 nm node.

A popular stressor layer is an alloy of germanium, or other semiconductors, and a metal, the most popular example being a germanium-tin alloy. Such alloys are commonly deposited on substrates with semiconductor materials and dielectric materials. Because the stressor layer is used to create stress in an adjacent semiconductor layer, it is usually desired that the germanium-tin alloy deposit on the semiconductor and not on a dielectric material.

Strained or unstrained germanium-tin alloys can also be used in other parts of CMOS devices, such as the channel and contact, by forming a germanium-tin alloy layer on a semiconductor material. An unstrained germanium-tin alloy may have a higher carrier mobility than pure germanium if the tin concentration is high enough to yield direct bandgap. Direct bandgap germanium-tin alloys may also be used in photonic devices such as lasers.

Thus, there is a continuing need for methods and apparatus for selectively forming metal-semiconductor alloy layers on a substrate.

### SUMMARY OF THE INVENTION

Method and apparatus for forming group IV semiconductive semiconductor-alloy layers on a semiconductor substrate are provided. A group IV semiconductive semiconductor-alloy layer may be formed on a substrate by positioning the substrate in a processing chamber, flowing a germanium precursor into the processing chamber, flowing a metal halide into the processing chamber, and growing the alloy layer epitaxially on the substrate. A group IV halide deposition control agent enhances selective deposition on semiconductive regions of the substrate. The germanium precursor may be a hydride, such as digermane, and the metal precursor may be a metal halide. Carrier gases such as hydrogen, argon, helium, and nitrogen may be used as components of the gas mixture. Halogen gases and hydrogen halide gases may also be used. The deposition process may be a CVD process, which may be a cyclical process. An ALD process may also be used.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram summarizing a method according to one embodiment.

FIG. 2 is a schematic diagram of an apparatus according to another embodiment.

FIG. 3 is a flow diagram summarizing a method according to another embodiment.

FIG. 4 is a flow diagram summarizing a method according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

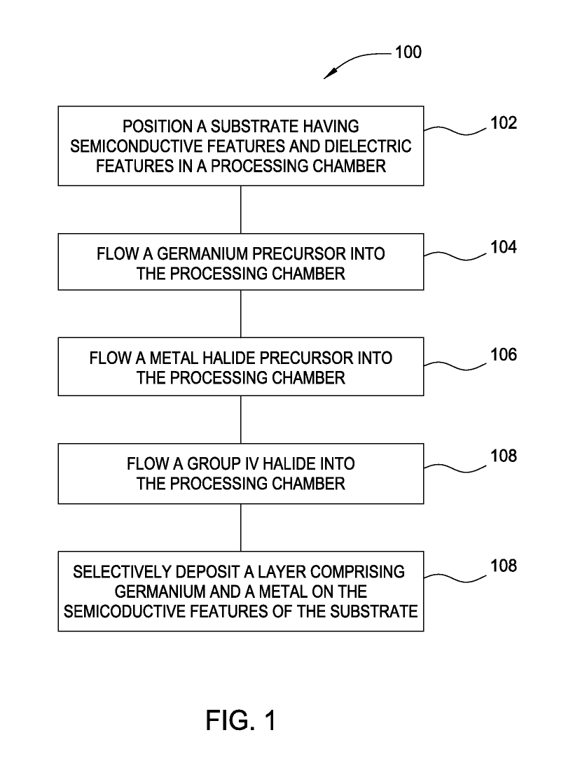

FIG. 1 is a flow diagram summarizing a method 100 according to one embodiment. A semiconductor substrate is positioned in a processing chamber at 102. The semiconductor substrate may be any semiconductive material on which a group IV semiconductive semiconductor-alloy layer is to be formed. A silicon substrate on which a transistor structure is to be formed may be used in one example. The substrate may have any known semiconductive materials, such as silicon, germanium, carbon, group III/V semiconductor materials, group II/VI semiconductor materials, and combinations or mixtures thereof. For example, the substrate may have silicon areas and germanium areas. The substrate may also have areas that are a mixture of silicon and germanium.

The semiconductor substrate may also have dielectric areas formed on a surface thereof. For example, a silicon substrate may have transistor gate structures and dielectric spacers formed adjacent to semiconductive source/drain regions, which may be regions of doped silicon or regions on which source/drain materials are to be formed. Thus, the source/drain regions may comprise the stressor layers described herein in addition to, or instead of, doped silicon layers. The dielectric areas may be oxides, nitrides, carbides, oxynitrides, oxycarbides, or combinations thereof. Metal oxides, metal nitrides, group IV oxides, group IV nitrides, group IV carbides, group IV oxynitrides, group IV, oxycarbides, low K dielectrics, high K dielectrics, glasses, ceramics, and combinations or mixtures thereof may be present in the substrate to be treated according to the method 100 of FIG. 1.

The group IV semiconductive semiconductor-alloy layers described herein typically comprise metal atoms disposed in a germanium matrix, GeₓM_{y}, or metal atoms disposed in a silicon-germanium matrix, SiₓGe_{y}M_{z}. In the silicon-germanium embodiments, if x, y, and z are normalized to sum to unity, x may be as high as 0.3. Said another way, the semiconductor-alloy layers described herein may be a germanium metal matrix having up to about 30 atomic percent silicon. Large metal atoms, for example group IV metals larger than germanium, such as tin and lead, are useful for adding compressive stress to a germanium or silicon-germanium matrix. A germanium crystal usually has a cubic structure with unit cell dimension about 566 pm. Each germanium atom has a radius of about 125 pm, while tin atoms have radius of about 145 pm, and lead has radius of between 155 and 180 pm. In an exemplary germanium matrix, adding the larger metal atoms to a germanium crystal matrix results in a larger lattice size that exerts a uniaxial compressive stress to lateral germanium atoms and/or biaxial tensile strain to overlying germanium atoms. Such strain alters the bandgap of the germanium, in certain cases resulting in higher carrier mobility compared to unstrained germanium.

In one aspect, the silicon substrate may have a germanium channel layer adjacent to the stressor layer as part of a transistor gate structure. The GeₓM_{y} or SiₓGe_{y}M_{z} stressor in this case applies a uniaxial stress onto the neighboring germanium layer. In another aspect, the germanium channel layer is deposited over the stressor layer, so that a biaxial tensile strain is applied to the germanium channel layer.

The group IV semiconductive semiconductor-metal alloy layers described herein can perform various functions in a CMOS transistor, such as stressor, channel, and/or contact. The alloy of germanium-tin by itself has a higher carrier mobility than germanium alone when the tin concentration is high enough to yield direct bandgap. For the same reason germanium-tin alloys can be used in photonic devices such as lasers. In applications such as the channel of a transistor, indirect bandgap is useful. Indirect bandgap may be maintained in a germanium-metal alloy by limiting the concentration of metal in the germanium matrix. Semiconductor-metal alloys may include germanium and silicon in some cases.

A germanium precursor is provided to the processing chamber containing the semiconductor substrate at 104. The germanium precursor is typically a germanium hydride, such as germane (GeH₄), digermane (Ge₂H₆), or higher hydrides (GeₓH₂ₓ₊₂), or a combination thereof. The germanium precursor may be mixed with a carrier gas, which may be a non-reactive gas such as nitrogen gas, hydrogen gas, or a noble gas such as helium or argon, or a combination thereof. The ratio of germanium precursor volumetric flow rate to carrier gas flow rate may be used to control gas flow velocity through the chamber. The ratio may be any proportion from about 1% to about 99%, depending on the flow velocity desired. In some embodiments, a relatively high velocity may improve uniformity of the formed layer. In a 300 mm single-wafer embodiment, the flow rate of germanium precursor may be between about 0.01 sLm and about 2.0 sLm. For a chamber having a volume of about 50 L, at the above flow rates for germanium precursor, carrier gas flow rate between about 5 sLm and about 40 sLm provides a uniform layer thickness.

A metal halide is provided to the processing chamber at 106 to react with the germanium precursor and deposit a layer of metal doped germanium or germanium-metal alloy. The metal halide may be a tin or lead halide gas, for example SnCl₄, SnCl₂, PbCl₄, or PbCl₂ or an organometallic chloride having the formula R_{X}MCl_{y}, where R is methyl or t-butyl, x is 1 or 2, M is Sn or Pb, and y is 2 or 3, such that the formed layer is composed primarily of group IV elements.

The metal halide is provided to the processing chamber at a flow rate between about 0.1 sccm and about 100 sccm, such as between about 5 sccm and about 20 sccm, for example about 10 sccm. The metal halide may also be mixed with a carrier gas to achieve a desired space velocity and/or mixing performance in the processing chamber. The metal halide may be sourced from a liquid or solid source of metal halide crystals evaporated or sublimed into a flowing carrier gas stream such as N₂, H₂, Ar, or He, or the metal halide may be generated by passing a halogen gas, optionally with one of the above carrier gases, over a solid metal in a contacting chamber to perform the reaction M+2Cl₂→MCl₄, where M is Sn or Pb. The contacting chamber may be adjacent to the processing chamber, coupled thereto by a conduit which is preferably short to reduce the possibility of metal halide particles depositing in the conduit.

At 108, a deposition control agent is provided to the processing chamber to control deposition on the surface of the substrate. The deposition control agent allows selective deposition on the semiconductive areas of the substrate at satisfactory deposition rates, while controlling deposition on dielectric areas, in some cases effectively preventing deposition on the dielectric areas. It is believed that the deposition control agent inhibits deposition on the dielectric regions of the substrate. Thus, the deposition control agent is a selectivity control agent because selectivity may be controlled by adjusting the amount of the selectivity control agent relative to the reactive species in the reaction mixture.

The deposition control agent is typically a halogen containing species, such as a group IV halide, for example dichlorosilane. Useful deposition control agents are typically fluorine containing agents, chlorine containing agents, or bromine containing agents, or mixtures thereof. Some may be fluorides, chlorides, and/or bromides, and some may be compounds containing more than one halogen species. The group IV components are usually silicon, germanium, carbon, or combinations thereof. Molecules including silicon and germanium, silicon and carbon, carbon and germanium, or silicon carbon and germanium may be used as deposition control agents. Organic chlorosilanes or organic chlorogermanes may be used, for example, along with their bromo-homologues. Exemplary deposition control agents include, but are not limited to, silicon tetrachloride, silicon tetrabromide, germanium tetrachloride, germanium tetrabromide, carbon tetrachloride, carbon tetrabromide, trichlorosilane, trichlorogermane, dichlorosilane, dichlorogermane, monochlorosilane, monochlorogermane, alkyl halosilanes having the formula RₓSiX₄₋ₓ, wherein x is 0 to 4, R is any alkyl or alkylene group, and X is Cl or Br, and alkyl halogermanes having the formula RₓGeX₄₋ₓ, wherein x is 0 to 4, R is any alkyl or alkylene group, and X is Cl or Br. Combination agents such as agents having the formula X¹ₓR₃₋ₓSiGeR′_{y}X²_{3-y} may also be used.

Usable alkyl halosilanes include chloromethylsilane, dichloromethylsilane, trichloromethylsilane, dichlorodimethylsilane, chlorodimethylsilane, chlorotrimethylsilane, bromomethylsilane, dibromomethylsilane, tribromomethylsilane, dibromodimethylsilane, bromodimethylsilane, bromotrimethylsilane, chloroethylsilane, dichloroethylsilane, trichloroethylsilane, dichlorodiethylsilane, chlorodiethylsilane, chlorotriethylsilane, bromoethylsilane, dibromoethylsilane, tribromoethylsilane, dibromodiethylsilane, bromodiethylsilane, bromotriethylsilane, chloromethylethylsilane, chlorodimethylethylsilane, chloromethyldiethylsilane, bromomethylethylsilane, bromodimethylethylsilane, bromomethyldiethylsilane, chloromethylgermane, dichloromethylgermane, trichloromethylgermane, dichlorodimethylgermane, chlorodimethylgermane, chlorotrimethylgermane, bromomethylgermane, dibromomethylgermane, tribromomethylgermane, dibromodimethylgermane, bromodimethylgermane, bromotrimethylgermane, chloroethylgermane, dichloroethylgermane, trichloroethylgermane, dichlorodiethylgermane, chlorodiethylgermane, chlorotriethylgermane, bromoethylgermane, dibromoethylgermane, tribromoethylgermane, dibromodiethylgermane, bromodiethylgermane, bromotriethylgermane, chloromethylethylgermane, chlorodimethylethylgermane, chloromethyldiethylgermane, bromomethylethylgermane, bromodimethylethylgermane, bromomethyldiethylsilane, fluoromethylsilane, difluoromethylsilane, trifluoromethylsilane, difluorodimethylsilane, fluorodimethylsilane, fluorotrimethylsilane, fluoromethylsilane, difluoromethylsilane, trifluoromethylsilane, difluorodimethylsilane, fluorodimethylsilane, fluorotrimethylsilane, fluoromethylethylsilane, fluorodimethylethylsilane, fluoromethyldiethylsilane, fluoromethylgermane, difluoromethylgermane, trifluoromethylgermane, difluorodimethylgermane, fluorodimethylgermane, fluorotrimethylgermane, fluoroethylgermane, difluoroethylgermane, trifluoroethylgermane, difluorodiethylgermane, fluorodiethylgermane, fluorotriethylgermane, fluoromethylethylgermane, fluorodimethylethylgermane, and fluoromethyldiethylgermane. It should be noted that compounds described above having more than one halogen, such as the di-halo, tri-halo, and tetra-halo compounds, may have mixed halogens. So, for example, a compound such as chlorobromosilane or fluorochlorosilane, or similar permutations of other compounds listed above, may be used. As those of skill in the art will appreciate from the foregoing non-exhaustive list, other variants of alkyl halosilanes and alkyl halogermanes are contemplated for use in practicing the methods described herein. Organic chlorides such as chloromethane, dichloromethane, and the like permuted similar to the list above, are also contemplated for use.

The deposition control agent may be provided at a flow rate between about 10 sccm and about 1000 sccm, such as between about 100 sccm and about 500 sccm, for example about 200 sccm. Layer growth selectivity and deposition rate may be controlled by adjusting a volumetric ratio of deposition control agent to germanium precursor. A higher ratio increases deposition rate overall and improves selectivity. The volumetric flow ratio of deposition control agent to germanium precursor ranges between about 1 and about 100 for most embodiments, such as between about 10 and about 60, for example about 30. At the upper end of the range the deposition rate is about 200 Å/min, while at the low end of the range the deposition rate is about 50 Å/min. However, at the upper end of the range, film growth on dielectric regions of the substrate is not observed, while at the lower end of the range, the deposition rate on the semiconductive regions is 1-2 times the deposition rate on the dielectric regions.

The metal halide and the germanium precursor may be provided to the processing chamber through different pathways. The germanium precursor may be provided through a first pathway and the metal halide provided through a second pathway. The first and second pathways are generally different and kept separate up to the point of entry into the processing chamber. In one embodiment, both streams enter through a side wall of the chamber proximate an edge of the substrate support, travel across the substrate support from one side to an opposite side thereof and into an exhaust system. The substrate support may rotate during formation of the semiconductor-metal alloy layer to improve uniformity. The first pathway generally communicates with a first entry point into the processing chamber, which may comprise one or more openings in a wall of the chamber or a gas distributor, such as a showerhead, coupled to a wall of the chamber. The one or more openings may be proximate an edge of the substrate support, as described above, or may be portals in a dual or multi path gas distributor. The second pathway likewise communicates with a second entry point similar to the first entry point. The first and second entry points are disposed such that the two streams mix and provide a deposition or layer growth mixture in a region above the substrate support. Use of a gas distributor may reduce or eliminate the need to rotate the substrate during processing in some embodiments.

The metal halide and the germanium precursor may also be mixed together outside the processing chamber and provided to the processing chamber through a single pathway. The deposition control agent may also be mixed together with the other precursors outside the processing chamber or provided to the processing chamber through a separate pathway.

Epitaxial growth of the semiconductor-metal alloy layer yields high structural quality. Pressure in the processing chamber is maintained between about 5 Torr and about 800 Torr, such as between about 20 Torr and about 120 Torr, for example about 80 Torr. Temperature is between about 150° C. and about 500° C., such as between about 200° C. and about 400° C., for example about 300° C. Temperatures are kept below a decomposition temperature of the metal halide precursor, generally about 600° C. or lower. Pressures may be below about 5 Torr in some embodiments, but reduced pressure also reduces deposition rate. Deposition rate at these conditions is between about 50 Å/min and about 500 Å/min.

A germanium metal alloy layer may include silicon, if a silicon containing deposition control agent is used. Similar reactions occur with the organometallic chlorides described above. Higher order germanes, such as digermane, yield a mix of chlorogermane intermediates, which similarly resolve into germanium deposits. Hydrogen, argon, helium, or nitrogen gas, or a mixture thereof, may be provided to the chamber to facilitate the deposition reactions. A flowrate of hydrogen gas between about 5 sLm and about 40 sLm may be included with any or all of the precursors to provide an ambient hydrogen concentration.

The layer is typically deposited to a thickness between about 100 Å and about 800 Å. Concentration of tin atoms in a matrix may be between about 1% and about 12%, such as between about 3% and about 9%, for example about 6%, according to the method 100. If lead is used, concentration of lead atoms in the matrix may be between about 0.2% and about 5%, such as between about 1% and about 3%, for example about 2%. A mixture of lead and tin may be used, if desired. Lead may achieve higher bandgap reduction at lower doses than tin, and using a mixture of lead and tin may be advantageous in some embodiments for delivering processability (i.e. tin halides are more stable than lead halides at elevated temperatures) with some enhancement of bandgap reduction.

The amount of compressive stress introduced by the semiconductor-metal alloy layer may be controlled at low metal concentrations by varying the concentration of metal incorporated in the matrix. The metal concentration may be controlled by adjusting a ratio of metal precursor to germanium precursor in the reaction mixture. For most embodiments, the ratio of volumetric flow rates of metal precursor to germanium precursor provided to the processing chamber will be between about 1% and about 40%, such as between about 4% and about 12%, for example about 8%. An atomic ratio of germanium to metal in the precursor gas mixture may be greater than 2:1, for example greater than 10:1.

The layers described herein may be formed using CVD methods that may be cyclic. Such methods may also be described as ALD methods. The germanium precursor may be provided to the processing chamber for a first duration, then stopped. Then the metal precursor may be provided to the processing chamber for a second duration, then stopped. This process may be repeated any number of times to achieve a desired layer thickness. The deposition control agent is usually provided continuously as the germanium and metal precursors are cyclically provided, but in other embodiments the germanium and metal precursors may be continuously or cyclically provided while the deposition control agent is intermittently provided at selected times. Carrier gases may also flow continuously with the deposition control agent and/or cyclically with the precursors.

The semiconductive semiconductor-metal alloy materials described herein may be doped, if desired, by including an appropriate dopant precursor in the gas mixture. Dopant sources such as borane, diborane, phosphine, and arsine are well known in the art and may be used as dopant precursors for doping a semiconductive semiconductor-metal alloy layer as described herein.

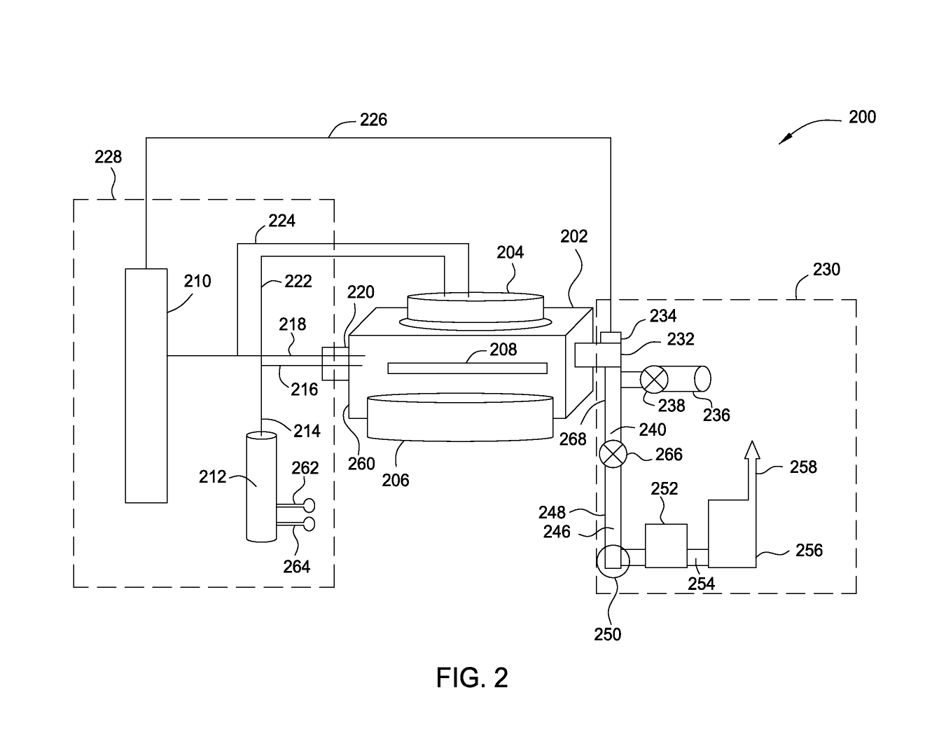

FIG. 2 is a schematic diagram of an apparatus 200 according to another embodiment. The apparatus 200 is useable for practicing the methods described herein for forming semiconductive semiconductor-metal alloy layers. A processing chamber 202 has a substrate support 208, which may be a rotating substrate support, disposed in an interior thereof. A heat source 206 is disposed facing one side of the substrate support 208. Alternately, a heat source may be embedded in the substrate support 208. The processing chamber 202 may have a showerhead 204 for gas entry into the chamber. Alternately, gas may be provided to the processing chamber through a side entry 220 coupled to a side wall 360 of the chamber 202.

A chamber with a heated substrate support as described in commonly assigned U.S. Pat. No. 7,172,792, entitled “Method for forming a high quality low temperature silicon nitride film”, issued Feb. 6, 2007, may be adapted to build the apparatus described herein and to practice the methods described herein. A chamber with a lamp heating module as described in commonly assigned U.S. Patent Publication 2008/0072820, entitled “Modular CVD Epi 300 mm Reactor”, published Mar. 27, 2008, may also be adapted to build the apparatus described herein and to practice the methods described herein. An Epi™ 300 mm reactor or a 300 mm×Gen™ chamber, both available from Applied Materials, Inc., of Santa Clara, Calif., may be adapted to make and use embodiments described herein, optionally with a CENTURA® platform, also available from Applied Materials, Inc. Other chambers from other manufacturers may also be used to practice the methods described herein.

A feed system 228, including a chemical delivery system 210 and a metal precursor contact chamber 212, is coupled to the chamber 202 through a variety of conduits. A first conduit 222 and a second conduit 224 may couple the feed system 228 to the optional showerhead 204. For performing the methods described herein, the showerhead 204 may be a dual-pathway showerhead to prevent mixing of the precursors prior to entry into the chamber 202. An exemplary dual-pathway showerhead is described in commonly assigned U.S. Pat. No. 6,983,892, entitled “Gas distribution showerhead for semiconductor processing”, issued Jan. 10, 2006.

Alternately, or additionally, cross-flow gas injection may be practiced by providing first and second cross-flow gas conduits 216 and 218 to the side entry point 220. An example of a cross-flow injection configuration is described in U.S. Pat. No. 6,500,734. The apparatus 200 may contain both a showerhead configuration and a cross-flow injection configuration, or only one or the other configuration.

The chemical delivery system 210 delivers germanium precursors, optionally with carrier gases such as nitrogen and/or hydrogen, to the chamber 202. The chemical delivery system 210 may also delivery deposition or selectivity control species to the chamber 202. The chemical delivery system 210 may include liquid or gaseous sources and controls (not shown), which may be configured in a gas panel.

The contact chamber 212 may be coupled to either the side entry point 220 or the showerhead 204 by a conduit 214 disposed to carry a metal precursor to the chamber 202. Conduits 214, 216, and 222 may be heated to a temperature between about 50° C. and about 200° C. to control or prevent condensation of metal halide species therein. The contact chamber 212 typically contains a bed of solid metal or metal halide crystals, or a bed of liquid metal halide such as tin tetrachloride. The metal halide may be evaporated or sublimed into a carrier gas provided through one or both of the gas feed conduits 262 and 264. The solid metal may be contacted with a halogen gas source provided through one or both of the gas feed conduits 262 and 264. In one embodiment, a halogen gas source is provided through a first gas feed conduit 262 while a carrier gas is provided through a second gas feed conduit 264. The gases, either for carrying vapor or reacting, may be flowed through a powdered metal or metal halide fluidized bed to enhance contacting. A mesh strainer or filter may be used to prevent entrainment of particles into the chamber 202. Alternately, the gases may flow across a fixed solid metal or metal halide bed.

An exhaust system 230 is coupled to the chamber 202. The exhaust system 230 may be coupled to the chamber at any convenient location, which may depend on the location of the gas entry into the chamber. For gas entry through the showerhead 204, the exhaust system may be coupled to a bottom wall of the chamber, around the heat source 206, for example, by one or more portals or through an annular opening. An annular manifold may be disposed near an edge of the substrate support and coupled to the exhaust system 230 in some embodiments. For cross-flow embodiments, the exhaust system 230 may be coupled to a side wall of the chamber opposite the side entry point 220.

An exhaust conduit 240 couples an exhaust cap 232 to a vacuum pump 252 through a throttle valve 266. A jacket 268 encompasses the exhaust conduit 240 and throttle valve 266 from the exhaust cap 232 to an inlet 250 of the vacuum pump 252. The jacket 268 enables thermal control of the exhaust conduit 240 to prevent condensation of exhaust species in the line. Any heating medium, such as steam, or hot air, water, or other hot fluid, may be used to maintain the exhaust conduit at a temperature above a dew point of the exhaust gas. Alternately, the jacket may include resistive heating elements (i.e. an electric blanket). A condensation trap 236 may be coupled to the exhaust conduit 240 by a valve 238, if desired, to further enhance trapping of any condensates in the exhaust system 230. The vacuum pump 252 pays off to an abatement system 256 through an abatement conduit 254, which is typically not heated or jacketed, and cleaned gas exhausted at 258. To further reduce wetting or nucleation in the exhaust conduit 240, the exhaust conduit 240 may be coated with quartz or with an inert polymer material.

Plasma or ultraviolet activated cleaning agents may be coupled into the exhaust system 230 by active source 234, which may be coupled to a microwave or RF chamber for generating active cleaning species. A cleaning gas line 226 may provide cleaning gases from the chemical delivery system 210 to the exhaust conduit 240, proceeding through the active source 234, if desired. Use of active species for cleaning allows cleaning to proceed at reduced temperatures.

A method for cleaning a chamber used to perform the methods described herein, such as the chamber 202, or any chamber used to perform the methods 100 and 200, includes providing a halogen gas to the chamber, converting residues to volatile halides. Temperature of the chamber is typically maintained below about 600° C. during cleaning, and metal deposits are converted to MClₓ, typically SnClₓ or PbClₓ. The halogen gas may be chlorine gas, fluorine gas, HBr, HCl, or HF. The chamber may be heated to an extent that separate heating of the exhaust conduit is not needed, especially if the exhaust conduit is insulated. Alternately, chamber temperature may be kept below about 400° C., if desired, and the exhaust conduit 240 heated to prevent condensation.

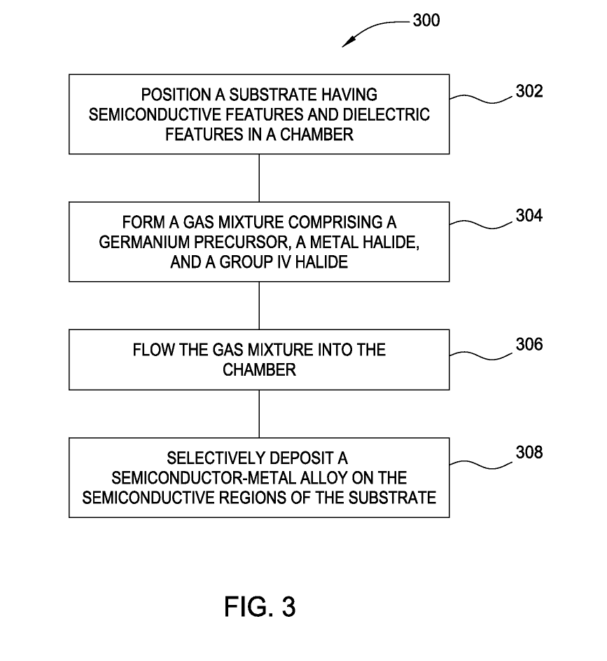

FIG. 3 is a flow diagram summarizing a method 300 according to another embodiment. At 302, a substrate having semiconductive regions and dielectric regions is disposed in a processing chamber. As described above in connection with FIG. 1, the substrate may have areas of silicon, germanium, mixtures and/or combinations of silicon and germanium, group III/V semiconductor materials, and/or group II/VI semiconductor materials. The substrate may also have regions of oxide, nitride, and carbide dielectric materials, such as metal oxides, metal nitrides, silicon oxides, silicon nitrides, silicon oxynitrides, silicon carbides, silicon oxycarbides, low k dielectric materials, high k dielectric materials, and the like. An exemplary substrate may have a silicon nitride layer surface and a silicon or germanium surface. The silicon or germanium surface may be exposed through an opening in the silicon nitride layer in some cases.

At 304, a gas mixture is formed comprising a germanium precursor, a metal halide, and a group IV halide. The various exemplars of these categories described above may be used to form the gas mixture at 304. The gas mixture may also include an inert gas, such as helium, argon, or nitrogen, a halogen gas, such as chlorine gas or bromine gas, and a hydrogen halide gas such as HCl and/or HBr.

At 306, the gas mixture is flowed into the chamber for application to the substrate. Pressure in the processing chamber is maintained between about 5 Torr and about 800 Torr, such as between about 20 Torr and about 120 Torr, for example about 80 Torr. Temperature is between about 150° C. and about 500° C., such as between about 200° C. and about 400° C., for example about 300° C.

At 308, a semiconductor-metal alloy layer is selectively formed on the semiconductive regions of the substrate. As described above, depending on the ratio of the group IV halide to the germanium precursor, the selectivity may be very high, resulting in essentially no deposition on the dielectric regions while forming the alloy layer on the semiconductive regions. It should, of course, be noted that the selectivity of the processes described herein may be controlled by adjusting the ratio of group IV halide to germanium precursor to yield a desired selectivity.

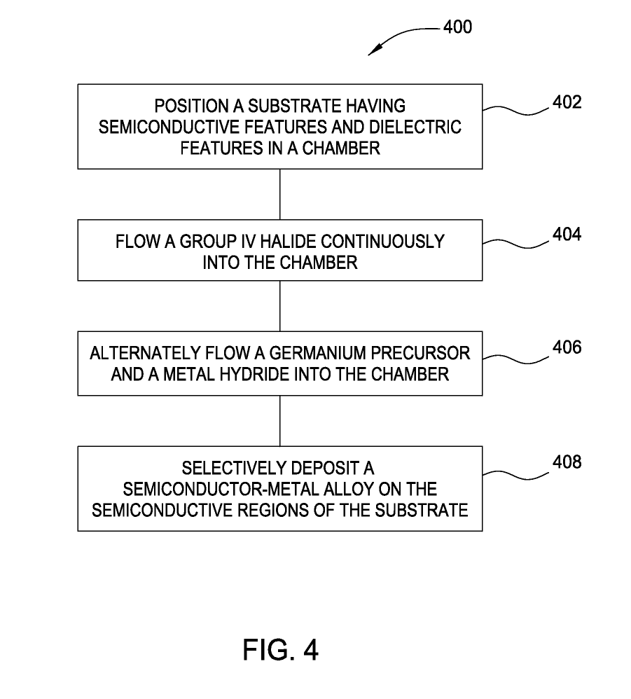

FIG. 4 is a flow diagram summarizing a method 400 according to another embodiment. The method 400 of FIG. 4 is another method of forming a semiconductor metal alloy on a substrate having semiconductive and dielectric features wherein the alloy is formed selectively on the semiconductive features using any of the materials described herein. At 402, a substrate having semiconductive and dielectric features according to any of the materials described elsewhere herein is positioned in a processing chamber. At 404, a group IV halide is provided to the chamber containing the substrate. The group IV halide is provided continuously and acts as a control agent for a deposition process or a layer growth process. The group IV halide may be any of the compounds, or a mixture of any of the compounds, described above.

At 406, a germanium precursor and a metal halide are alternately provided to the chamber to form a semiconductor metal alloy on the substrate in a cyclical process, which may be a pulsed CVD or ALD process. Each precursor is provided to the process chamber for a short duration to allow a layer to form from the precursor on the substrate Temperatures, pressures, and flow rates may be as described elsewhere herein. For example, the germanium precursor may be provided to the chamber for a duration of about 1 sec to about 30 sec, for example 3 sec, and then flow of the germanium precursor may be stopped for a duration of 1-5 sec to purge the germanium precursor from the chamber. Then the metal halide may be provided to the chamber for a duration of about 1 sec to about 30 sec, for example 3 sec, and then flow of the metal halide may be stopped for 1-5 sec to purge the metal halide from the chamber.

At 408, a semiconductor metal alloy material is selectively formed on the semiconductive features of the substrate. The material is formed by successive cycles of providing the germanium precursor and the metal halide precursor to the chamber while the group IV halide flows continuously. As with the other methods described herein, flow rates of the germanium precursor and the metal halide precursor relative to the group IV halide may be adjusted to control growth rate and selectivity of the semiconductor metal alloy.

In one example, 15 sccm of digermane, 1 sccm of tin (IV) chloride, and 500 sccm of dichlorosilane are flowed into a chamber having a substrate with a germanium surface and a silicon nitride layer formed over a portion of the germanium surface. The chamber is maintained at 80 Torr and 300° C. for about 2 minutes. A layer of semiconductor-metal alloy was observed to form on the germanium surface to a thickness of about 175 Å. Essentially no deposition on the silicon nitride region was observed.

Alternate embodiments of forming a semiconductive semiconductor-metal alloy layer may include cyclical processes of forming a substantially pure epitaxial germanium layer and then forming a metal-doped epitaxial germanium layer, the pure and doped layers formed by starting and stopping flow of the metal precursor while maintaining flow of the germanium precursor, generally according to recipes described above. In other embodiments, a layer having graded stress may be formed by establishing flow of the germanium precursor for a period of time to form an epitaxial initial layer of substantially pure germanium, starting flow of the metal precursor at an initial flow rate, and then increasing the flow rate of the metal precursor to a final flow rate according to any desired pattern, linear or non-linear. Such a graded stress layer may adhere to underlying layers more strongly while providing increased electron mobility.

The deposition control agents described herein can also be used to increase the growth rate and metal concentration in the semiconductive semiconductor-metal alloy. Growth rate of the alloy may be controlled by adjusting the flow rate of deposition control agent. Metal concentration in the alloy may also be controlled by adjusting the flow rate of deposition control agent. For example when 500 sccm of dichlorosilane is co-flowed with digermane and tin tetrachloride at 80 Torr and 300° C., a layer is formed at a growth rate of approximately 80 Å/min and the layer has a tin concentration of about 10%, whereas if no dichlorosilane is used at the same conditions growth rate of the layer is approximately 60 Å/min and the tin concentration is about 7%. Thus, metal concentration and layer growth rate may be increased by increasing the flow rate of deposition control agent, or decreased by decreasing the flow rate of deposition control agent.

While the foregoing is directed to embodiments of the invention, other and further embodiments of the invention may be devised without departing from the basic scope thereof.

1. A method of forming a group IV semiconductive semiconductor-metal alloy layer on a substrate having semiconductive materials and dielectric materials, comprising:
positioning the substrate in a processing chamber;
forming a gas mixture comprising a germanium precursor, a metal halide, and a group IV halide in a mixing volume;
flowing the gas mixture into the processing chamber; and
selectively forming a germanium metal alloy layer on the semiconductive materials of the substrate.

2. The method of claim 1, wherein the group IV halide is a fluorine containing compound, a chlorine containing compound, a bromine containing compound, or a mixture thereof.

3. The method of claim 1, wherein the group IV halide is a chlorosilane.

4. The method of claim 2, wherein the germanium precursor is a germanium hydride gas, and the metal halide is a metal chloride.

5. The method of claim 4, wherein the gas mixture further comprises a halogen gas or a hydrogen halide.

6. The method of claim 5, wherein the gas mixture further comprises hydrogen gas, nitrogen gas, argon gas, helium gas, or a mixture thereof.

7. The method of claim 1, wherein the gas mixture has a ratio of germanium atoms to metal atoms that is greater than 2:1.

8. The method of claim 1, wherein selectively forming a germanium metal alloy layer on the semiconductive materials of the substrate comprises maintaining a temperature of the substrate between about 150° C. and about 500° C.

9. The method of claim 8, wherein the gas mixture has a ratio of germanium atoms to metal atoms that is greater than 2:1.

10. The method of claim 9, wherein the group IV halide is a fluorine containing compound, a chlorine containing compound, a bromine containing compound, or a mixture thereof.

11. The method of claim 10, wherein the germanium precursor is a germanium hydride.

12. The method of claim 8, wherein the germanium precursor and the metal halide are flowed into the chamber through a showerhead.

13. The method of claim 4, wherein the group IV halide inhibits deposition on the dielectric regions of the substrate.

14. The method of claim 2, wherein the growing the group IV semiconductive semiconductor-metal alloy layer epitaxially on the substrate comprises maintaining the processing chamber at a pressure between about 5 Torr and about 800 Torr and a temperature between about 150° C. and about 400° C.

15. The method of claim 2, wherein the semiconductive material of the substrate is germanium and the dielectric material of the substrate is silicon nitride.

16. A method of forming a layer on a substrate, comprising:
disposing the substrate in a processing chamber;
flowing a group IV halide through the processing chamber;
alternately flowing a germanium hydride and a metal halide through the chamber; and
selectively forming a germanium metal alloy layer on semiconductive regions of the substrate.

17. The method of claim 16, wherein the group IV halide comprises a first element selected from the group consisting of silicon, germanium, and carbon and a second element selected from the group consisting of fluorine, chlorine, or bromine.

18. The method of claim 17, wherein the metal halide is tin (IV) chloride.

19. The method of claim 18, wherein the semiconductive regions of the substrate comprise silicon or germanium.

20. The method of claim 19, wherein the germanium metal alloy layer comprises silicon.

21. The method of claim 16, wherein the germanium metal alloy layer is doped with boron, phosphorus, and/or arsenic by providing borane, diborane, phosphine, and/or arsine to the chamber while forming the germanium metal alloy layer.

22. The method of claim 16, further comprising controlling a growth rate of the germanium metal alloy layer by adjusting a flow rate of the group IV halide.

23. The method of claim 16, further comprising controlling a metal content of the germanium metal alloy layer by adjusting a flow rate of the group IV halide.
